(19) United States
(12) Patent Application Publication
(10) Pub. No.: US 2018/0047840 A1
(43) Pub. Date: Feb. 15, 2018

(54) SEMICONDUCTOR DEVICE AND SEMICONDUCTOR DEVICE MANUFACTURING METHOD

(71) Applicant: FUJITSU LIMITED, Kawasaki-shi (JP)

(72) Inventors: Norikazu NAKAMURA, Sagamihara (JP); Junji KOTANI, Atsugi (JP)

(73) Assignee: FUJITSU LIMITED, Kawasaki-shi (JP)

(21) Appl. No.: 15/791,878

(22) Filed: Oct. 24, 2017

Related U.S. Application Data
(63) Continuation of application No. PCT/JP2015/063361, filed on May 8, 2015.

(51) Int. Cl. H01L 29/778; H01L 21/02; H01L 29/66; H01L 29/20; H01L 29/205

(52) U.S. Cl. CPC H01L 29/7787; H01L 29/2003; H01L 29/205; H01L 29/66462; H01L 21/0262; H01L 21/02381; H01L 21/02458; H01L 21/02505; H01L 21/0251; H01L 21/0254; H01L 21/3065

(57) ABSTRACT

A semiconductor device includes a first semiconductor layer formed of a nitride semiconductor above a substrate, a second semiconductor layer formed of a material including InAlN or InAlGaN above the first semiconductor layer, a third semiconductor layer formed of a material including AlN above the second semiconductor layer, a fourth semiconductor layer formed of a material including GaN above the third semiconductor layer, a gate electrode formed above the fourth semiconductor layer, and a source electrode and a drain electrode formed on any one of the second semiconductor layer, the third semiconductor layer, and the fourth semiconductor layer.

### CROSS-REFERENCE TO RELATED APPLICATION

This application is a continuation application of Internal Application PCT/JP2015/063361 filed on May 8, 2015 and designated the U.S., the entire contents of which are incorporated herein by reference.

### FIELD

The embodiments discussed herein are related to a semiconductor device and a semiconductor device manufacturing method.

### BACKGROUND

A nitride semiconductor such as GaN, AlN, or InN, or a material constituted of a mixed crystal of these semiconductors, has a wide band gap, and is used for a high power electronic device, a short wavelength light emitting device, and the like. For instance, GaN which is a nitride semiconductor has a band gap of 3.4 eV, which is larger than the band gap of Si (1.1 eV) and the band gap of GaAs (1.4 eV).

One of the high power electronic devices using a nitride semiconductor is an FET (Field Effect Transistor), especially an HEMT (High Electron Mobility Transistor) (see Japanese Laid-Open Patent Publication No. 2013-77620, for example). An HEMT using a nitride semiconductor is used for a high-power and high-efficiency amplifier, a high-power switching device, and the like. Specifically, in an HEMT using AlGaN in an electron supply layer and using GaN in an electron transit layer, distortion occurs due to the difference in lattice constants between AlGaN and GaN. The occurrence of the distortion leads to piezoelectric polarization and the like, and high concentration of two-dimensional electron gas (2 DEG) is generated. Therefore, the HEMT using AlGaN in an electron supply layer and using GaN in an electron transit layer can operate at a high voltage, and can be used for a high-efficiency switching device or a high voltage-resistant power device for an electric vehicle.

To have high output, some ultra-high frequency devices using the nitride semiconductor adopt InAlN having a high spontaneous polarization in the electron supply layer, instead of AlGaN. Since InAlN can induce high concentration of two-dimensional electron gas even if the thickness of the layer of InAlN is thin, it is attracting attention as a material having both high output property and high-frequency performance.

To improve morphology or to prevent oxidation on the surface, GaN cap layer may be formed on the electron supply layer. The GaN cap layer may be formed not only in the HEMT using AlGaN in the electron supply layer, but also in an HEMT using InAlN in the electron supply layer. By forming the GaN cap layer, the reliability of the semiconductor device improves.

In the HEMT using InAlN in the electron supply layer, preferable growth temperature of the GaN cap layer formed on the electron supply layer is different from the temperature preferable for growing InAlN forming the electron supply layer. Hence, when the GaN cap layer is formed on the electron supply layer formed of InAlN, the characteristics of the semiconductor device are degraded. Note that the HEMT using AlGaN in the electron supply layer does not have the problem mentioned above since the preferable growth temperature of the GaN cap layer formed on the electron supply layer is the same as the preferable growth temperature of the electron supply layer formed of AlGaN.

The followings are reference documents:

[Patent Document 1] Japanese Laid-Open Patent Publication No. 2013-77620,

[Patent Document 2] Japanese Laid-Open Patent Publication No. 2013-207107.

### SUMMARY

According to an aspect of the embodiments, a semiconductor device includes a first semiconductor layer formed of a nitride semiconductor above a substrate, a second semiconductor layer formed of a material including InAlN or InAlGaN above the first semiconductor layer, a third semiconductor layer formed of a material including AlN above the second semiconductor layer, a fourth semiconductor layer formed of a material including GaN above the third semiconductor layer, a gate electrode formed above the fourth semiconductor layer, and a source electrode and a drain electrode each formed on one of the second semiconductor layer, the third semiconductor layer, and the fourth semiconductor layer.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF THE DRAWINGS

FIG. 1 is a drawing illustrating a structure of a semiconductor device using InAlN in an electron supply layer;

FIG. 2 is a drawing illustrating a structure of a semiconductor device according to a first embodiment;

FIGS. 3A to 3C are views illustrating steps of manufacturing the semiconductor device according to the first embodiment;

FIGS. 4A to 4C are views illustrating steps of manufacturing the semiconductor device according to the first embodiment;

FIG. 5 illustrates current-voltage characteristics (I-V characteristics) of the semiconductor device according to the first embodiment;

FIG. 6 illustrates I-V characteristics of the semiconductor device illustrated in FIG. 1;

FIG. 7 is a drawing illustrating a structure of another semiconductor device according to the first embodiment;

FIG. 8 is a drawing illustrating a structure of a semiconductor device according to a second embodiment;

FIGS. 9A to 9C are views illustrating steps of manufacturing the semiconductor device according to the second embodiment;

FIGS. 10A to 10C are views illustrating steps of manufacturing the semiconductor device according to the second embodiment;

FIG. 11 is a view illustrating a step of manufacturing the semiconductor device according to the second embodiment;

FIG. 12 is a drawing illustrating a structure of another semiconductor device according to the second embodiment;

FIG. 13 is a diagram illustrating a semiconductor device package according to a third embodiment;

FIG. 14 illustrates a circuit diagram of a PFC circuit according to the third embodiment;

FIG. 15 illustrates a circuit diagram of a power supply unit according to the third embodiment; and

FIG. 16 is a diagram illustrating a structure of a high-frequency amplifier according to the third embodiment.

### DESCRIPTION OF EMBODIMENTS

Embodiments will be described below. Note that, in explaining embodiments, the same symbol is attached to the same component, and repeated explanation about the same component is omitted.

### First Embodiment

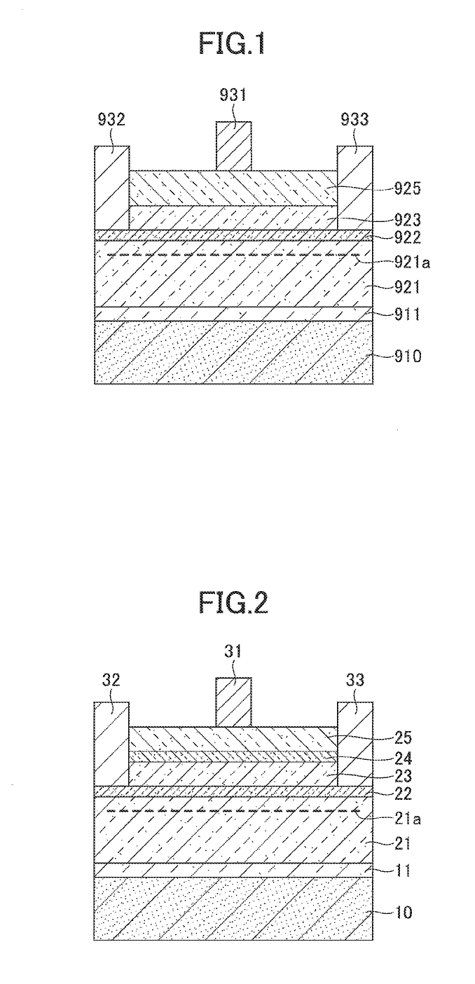

First, with reference to FIG. 1, an HEMT which is a semiconductor device using InAlN in an electron supply layer will be described. As illustrated in FIG. 1, the semiconductor device using InAlN in an electron supply layer is formed so that a nucleation layer (not illustrated in the drawings), a buffer layer 911, an electron transit layer 921, a spacer layer 922, the electron supply layer 923, and a cap layer 925 are layered sequentially on the substrate 910. A silicon (Si) substrate is used as the substrate 910, and the nucleation layer is formed of AlN. The buffer layer 911 is formed of AlGaN, and may be doped with approximately 3×10¹⁷ atoms/cm³ of Fe as an impurity element to have high resistance. The electron transit layer 921 is formed of GaN, the spacer layer 922 is formed of AlN, the electron supply layer 923 is formed of InAlN, and the cap layer 925 is formed of GaN. Because of this structure, 2 DEG 921a is generated in the electron transit layer 921 near the interface of the electron transit layer 921 and the spacer layer 922. Further, a gate electrode 931 is formed on the cap layer 925, and a source electrode 932 and a drain electrode 933 are formed on the spacer layer 922.

In the semiconductor device illustrated in FIG. 1, nitride semiconductor layers are formed through epitaxial growth using MOVPE (Metal Organic Vapor Phase Epitaxy). That is, the nucleation layer (not illustrated), the buffer layer 911, the electron transit layer 921, the spacer layer 922, the electron supply layer 923, and the cap layer 925 are formed through epitaxial growth using MOVPE. Preferable growth temperature in forming AlN, AlGaN, and GaN by MOVPE is almost the same, that is, around 1000° C. (degrees Celsius). On the other hand, in forming InAlN, if the temperature is high when InAlN is epitaxially grown, In having high vapor pressure is desorbed and defects occur. Therefore, the preferable growth temperature in forming InAlN by MOVPE is 740° C., which is less than the preferable growth temperature in forming GaN and the like.

Consider the case of forming the cap layer 925 on the electron supply layer 923 at the same temperature as the temperature in forming the electron supply layer 923, which is the case for forming GaN on the InAlN layer at the same temperature as the temperature in forming InAlN (that is, 740° C.). In this case, since GaN formed as the cap layer 925 is grown at the temperature less than the preferable temperature of GaN, a large amount of carbon (C) is taken inside GaN constituting the cap layer 925. Because an organic metal gas is used for a source gas in MOVPE, a large amount of carbon component is taken in a film formed by MOVPE if the growth temperature is low. When a large amount of carbon (C) is taken inside GaN constituting the cap layer 925, many defects occur, which causes a current collapse phenomenon since an electron is trapped by the defects.

Next, consider the case of forming the cap layer 925 on the electron supply layer 923 at the temperature preferable for the cap layer 925 which is higher than the temperature in forming the electron supply layer 923, which is the case for forming GaN on the InAlN layer at the temperature of 1000° C. which is higher than the temperature in forming InAlN. In this case, since GaN formed as the cap layer 925 is epitaxially grown at the temperature preferable for forming GaN, the amount of C (carbon) taken inside GaN becomes less than the case described earlier. However, since it is required to raise the temperature just before growing GaN for example, In is desorbed from a surface of InAlN. When In is desorbed from the surface of InAlN, the portion where In is desorbed becomes a defect, which causes the current collapse phenomenon since an electron is trapped by the defect.

As described above, in forming the cap layer 925 constituted by GaN on the electron supply layer 923 constituted by InAlN, the current collapse phenomenon occurs in the semiconductor device regardless of whether the growth temperature of GaN constituting the cap layer 925 is high or low. The occurrence of the current collapse phenomenon is not preferable for the semiconductor device since it increases on-resistance and the characteristics of the semiconductor device degrade.

Accordingly, in the semiconductor device where the electron supply layer is formed of InAlN and the cap layer is formed of GaN, a semiconductor device is required in which the current collapse phenomenon is less likely to occur and good characteristics are ensured. One reason the cap layer of GaN is formed in the semiconductor device is that GaN can form a film having a flat surface since GaN is grown horizontally, in contrast to the surface of the film formed by AlGaN, InAlN, AlN, or the like not being especially flat. By forming a film of GaN on the surface of the nitride semiconductor layers, a flat surface for the nitride semiconductor layers is enabled, which contributes to improving withstand voltage and a yield rate of the semiconductor device, to equalizing the characteristics of the semiconductor device, and so on.

### <Semiconductor Device>

Next, the semiconductor device according to the present embodiment will be described. In the semiconductor device according to the present embodiment, as illustrated in FIG. 2, a nucleation layer (not illustrated), a buffer layer 11, an electron transit layer 21, a spacer layer 22, an electron supply layer 23, a desorption prevention layer 24, and a cap layer 25 are layered sequentially on a substrate 10. A gate electrode 31 is formed on the cap layer 25, and a source electrode 32 and a drain electrode 33 are formed on the spacer layer 22. Note that the source electrode 32 and the drain electrode 33 may be formed on the electron supply layer 23, the desorption prevention layer 24, or the cap layer 25. Hence, the desorption prevention layer 24 may be formed at the area between the source electrode 32 and the drain electrode 33. In the present application, the electron transit layer 21 may be called a first semiconductor layer, the spacer layer 22 may be called a fifth semiconductor layer, the electron supply layer 23 may be called a second semiconductor layer, the desorption prevention layer 24 may be called a third semiconductor layer, and the cap layer 25 may be called a fourth semiconductor layer.

A silicon substrate is used as the substrate 10, and the nucleation layer is formed of AlN. The buffer layer 11 is formed of AlGaN, and may be doped with 3×10¹⁷ atoms/cm³ of Fe as an impurity element to have high resistance. The electron transit layer 21 is formed of GaN, the spacer layer 22 is formed of AlN, the electron supply layer 23 is formed of InAlN, the desorption prevention layer 24 is formed of AlN, and the cap layer 25 is formed of GaN. Because of this structure, 2 DEG 21a is generated in the electron transit layer 21 near the interface of the electron transit layer 21 and the spacer layer 22.

In the semiconductor device according to the present embodiment, the nucleation layer (not illustrated), the buffer layer 11, the electron transit layer 21, the spacer layer 22, the electron supply layer 23, the desorption prevention layer 24, and the cap layer 25, which are nitride semiconductor layers, are formed through epitaxial growth using MOVPE.

As described above, the preferable growth temperature in forming AlN, AlGaN, or GaN by MOVPE is almost the same, that is, approximately 1000° C. On the other hand, if the temperature is high when InAlN is epitaxially grown, In having high vapor pressure is desorbed, and defects occur. Therefore, the preferable growth temperature in forming InAlN by MOVPE is 740° C.

According to the present embodiment, after the electron supply layer 23 has been formed using InAlN, an extremely thin desorption prevention layer 24 is formed of AlN at the temperature of 740° C., which is the same as the temperature in forming the electron supply layer 23. By forming the desorption prevention layer 24 using AlN on the electron supply layer 23 formed of InAlN, desorption of In from the surface of InAlN can be avoided, even if the temperature is raised up to approximately 1000° C. in forming the cap layer 25. Because of the desorption prevention layer 24 formed of AlN, the cap layer 25 constituted by GaN can be formed at the temperature of about 1000° C. which is the preferable growth temperature for forming GaN, so that the cap layer 25 having a low C concentration can be formed. Accordingly, in the semiconductor device according to the present embodiment, a defect does not occur in the electron supply layer 23 or the cap layer 25. Thus, the current collapse phenomenon is less likely to occur since an electron is not trapped in these semiconductor layers. Therefore according to the present embodiment, even with respect to a semiconductor device in which the electron supply layer 23 is formed of InAlN and the cap layer 25 is formed of GaN, good characteristics can be ensured.

Instead of a silicon substrate, GaN substrate, a sapphire substrate, SiC substrate or the like may be used as the substrate 10. If a silicon substrate is used as the substrate 10, as described earlier, it is preferable that the buffer layer 11 is formed above the substrate 10.

Also, InAlGaN may be used as the electron supply layer 23 instead of InAlN. Also, it is preferable that the thickness of AlN formed as the desorption prevention layer 24 is not less than 0.2 nm and not more than 2 nm, and more preferably is not less than 0.2 nm and not more than 1 nm. If the desorption prevention layer 24 is too thin, it cannot prevent In from being desorbed from InAlN sufficiently. Additionally, if the desorption prevention layer 24 is too thick, a crack occurs in the desorption prevention layer 24 and the layer cannot prevent In from being desorbed from InAlN.

Further, it is preferable that the concentration of carbon contained in the cap layer 25 is not more than 1×10¹⁷ atoms/cm³, and more preferably, is not more than 5×10¹⁶ atoms/cm³. If the concentration of carbon contained in the cap layer 25 is too high, the current collapse phenomenon is likely to occur. Therefore it is preferable that the concentration of carbon contained in the cap layer 25 is low.

### <Manufacturing Method of the Semiconductor Device>

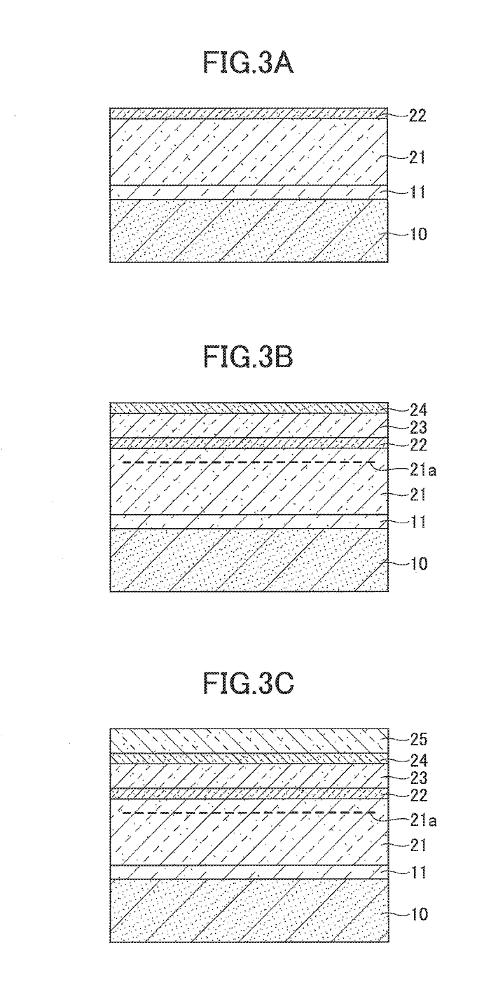

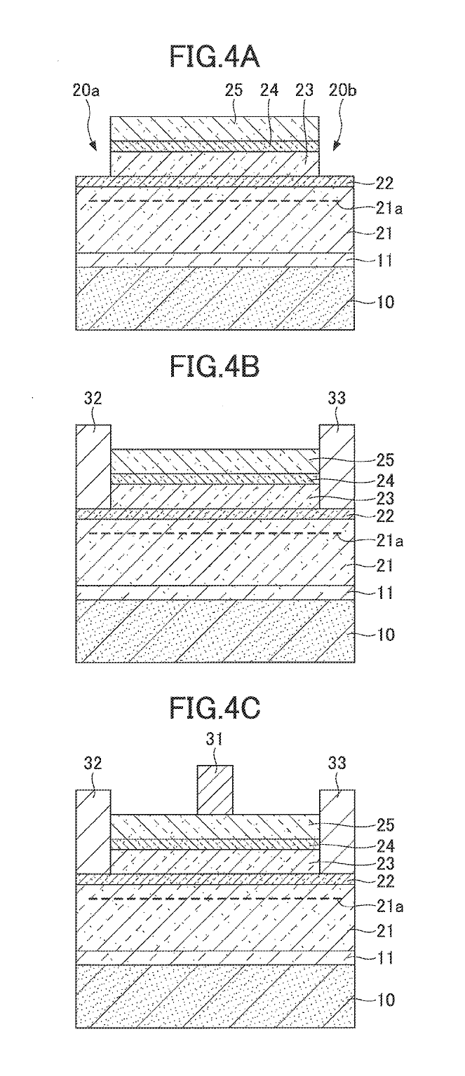

Next, with reference to FIGS. 3 and 4, a method of manufacturing the semiconductor device according to the present embodiment will be described.

First, as illustrated in FIG. 3A, the process of forming the nucleation layer (not illustrated), the buffer layer 11, the electron transit layer 21, and the spacer layer 22 sequentially on a substrate 10 through epitaxial growth using MOVPE is performed.

Specifically, a silicon substrate is used as the substrate 10. The nucleation layer not illustrated is formed by depositing AlN film with supplying trimethylaluminium (TMA) and NH₃ in the MOVPE chamber as a source gas, under the condition that the growth temperature is 1000° C. and the growth pressure is 20 kPa.

The buffer layer 11 is formed by depositing AlGaN film with supplying trimethylgallium (TMG), TMA and NH₃ in the MOVPE chamber as a source gas, under the condition that the growth temperature is 1000° C. and the growth pressure is 20 kPa. The buffer layer 11 is formed by layering three layers of AlGaN films each of which has a different composition ratio. Specifically, the buffer layer 11 is formed so that Al_{0.8}Ga_{0.2}N film, Al_{0.5}Ga_{0.5}N film, and Al_{0.2}Ga_{0.8}N film are layered sequentially on the nucleation layer. The AlGaN films having different composition ratios can be formed by performing deposition while varying the supply ratios of TMA and TMG that are supplied to the chamber. Further, the buffer layer 11 may be doped with approximately 3×10¹⁷ atoms/cm³ of Fe. To dope the buffer layer 11 with Fe, cyclopentadienyl iron (Cp₂Fe) may be supplied during deposition.

The electron transit layer 21 is formed by depositing GaN film having a thickness of about 1 μm while supplying TMG and NH₃ in the MOVPE chamber as a source gas, under the condition that the growth temperature is 1000° C. and the growth pressure is 20 kPa.

The spacer layer 22 is formed by depositing AlN film having a thickness of about 1 nm while supplying TMA and NH₃ in the MOVPE chamber as a source gas, under the condition that the growth temperature is 1040° C. and the growth pressure is 5 kPa.

Next, after lowering the temperature of the substrate to about 740° C., as illustrated in FIG. 3B, the process of forming the electron supply layer 23 and the desorption prevention layer 24 sequentially on the spacer layer 22 is performed.

The electron supply layer 23 is formed by depositing In_{0.17}Al_{0.83}N film having a thickness of about 10 nm while supplying trimethylindium (TMI), TMA and NH₃ in the MOVPE chamber as a source gas, under the condition that the growth temperature is 740° C. and the growth pressure is 5 kPa.

The desorption prevention layer 24 is formed by stopping the supply of TMI just before completing the deposition of the electron supply layer 23 in the process of depositing the electron supply layer 23, and depositing AlN film having a thickness of about 1 nm. Accordingly, the electron supply layer 23 and the desorption prevention layer 24 are formed by continuous growth. By forming the nitride semiconductor layers as described here, 2 DEG 21a is generated in the electron transit layer 21 near the interface of the electron transit layer 21 and the spacer layer 22.

Next, after raising the temperature of the substrate to about 1000° C. again, the process of forming the cap layer 25 on the desorption prevention layer 24 is performed, as illustrated in FIG. 3C.

The cap layer 25 is formed by depositing GaN film having a thickness of about 10 nm while supplying TMG and NH₃ in the MOVPE chamber as a source gas, under the condition that the growth temperature is 1000° C. and the growth pressure is 20 kPa.

Next, after forming an element isolation region which is not illustrated in the drawings, a process of forming openings 20a and 20b is performed as illustrated in FIG. 4A, by removing the nitride semiconductor layers at locations where the source electrode 32 and the drain electrode 33 are to be formed.

Specifically, the element isolation region which is not illustrated in the drawings is formed by performing the following processes. First, a photoresist pattern (not illustrated in the drawings) is formed having an opening at locations where the element isolation region is to be formed, by applying the photoresist on the cap layer 25 and performing exposure and development processing using an exposing apparatus. Subsequently, by performing dry etching to remove a part of the nitride semiconductor layers at the opening of the photoresist pattern, or by performing ion implantation to the part of the nitride semiconductor layers, the element isolation region which is not illustrated in the drawings is formed. After the process, the photoresist pattern (not illustrated in the drawings) is removed using an organic solvent.

Next, a photoresist is applied on the cap layer 25 again, and the exposure and development processing are performed using the exposing apparatus, to form a photoresist pattern (not illustrated in the drawings) having openings at locations where the source electrode 32 and the drain electrode 33 are to be formed. Subsequently, the cap layer 25, the desorption prevention layer 24, and the electron supply layer 23 existing at the area of the nitride semiconductor layers where the photoresist pattern does not exist are removed by performing dry etching such as RIE (Reactive Ion Etching). By performing this process, on the nitride semiconductor layers, the openings 20a and 20b are formed at the locations where the source electrode 32 and a drain electrode 33 are to be formed. Subsequently, the photoresist pattern (not illustrated in the drawings) is removed using an organic solvent. In the RIE performed here, a gas containing a chlorine component is used as an etching gas.

Next, as illustrated in FIG. 4B, a process of forming the source electrode 32 and the drain electrode 33 is performed. Specifically, a photoresist is applied on the cap layer 25 and the spacer layer 22 which is exposed at the openings 20a and 20b, and the exposure and development processing using the exposing apparatus are performed, to form a photoresist pattern (not illustrated in the drawings) having an opening at the locations where the source electrode 32 and the drain electrode 33 are to be formed. Subsequently, after a metal multilayered film of Ta (20 nm)/Al (200 nm) is formed through a vacuum vapor deposition, by immersing in an organic solvent, the metal multilayered film which is deposited on the photoresist pattern is removed together with the photoresist pattern by lift-off process. As a result of performing this process, by the metal multilayered film remaining on the spacer layer 22, the source electrode 32 is formed at the opening 20a on the nitride semiconductor layers and the drain electrode 33 is formed at the opening 20b on the nitride semiconductor layers. Subsequently, the nitride semiconductor layers are heat-treated in a nitrogen atmosphere at a temperature of about 400° C. to 1000° C., at 550° C. for example, to establish ohmic contact.

Next, as illustrated in FIG. 4C, a process of forming the gate electrode 31 on the cap layer 25 is performed. Specifically, a photoresist is applied on the cap layer 25, the source electrode 32, and the drain electrode 33, and the exposure and development processing using the exposing apparatus are performed, to form a photoresist pattern (not illustrated in the drawings) having an opening at a location where the gate electrode 31 is to be formed. Subsequently, after a metal multilayered film of Ni (30 nm)/Au (400 nm) is formed through a vacuum vapor deposition, by immersing in an organic solvent, the metal multilayered film which is deposited on the photoresist pattern is removed together with the photoresist pattern by lift-off process. As a result of this process, the gate electrode 31 is formed by the metal multilayered film remaining on the cap layer 25.

According to these processes, the semiconductor device according to the present embodiment is manufactured.

### <Characteristics of Semiconductor Device>

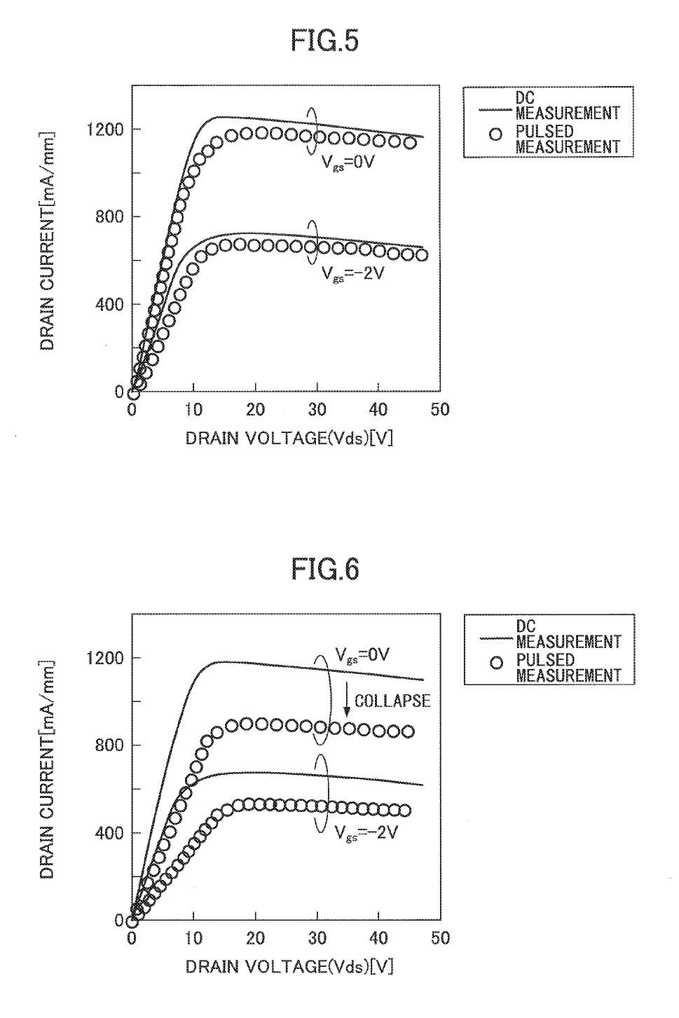

Next, characteristics of the semiconductor device according to the present embodiment will be described. FIG. 5 illustrates a measured result of I-V characteristics of the semiconductor device according to the present embodiment. FIG. 6 illustrates a measured result of I-V characteristics of the semiconductor device having a structure illustrated in FIG. 1. Note that the semiconductor device according to the present embodiment is manufactured with the method of manufacturing the semiconductor device described above. Also, a method of manufacturing the semiconductor device having the structure illustrated in FIG. 1 is similar to the method of manufacturing the semiconductor device according to the present embodiment described above, except that the process for forming the desorption prevention layer 24 is not executed and that the condition for depositing the cap layer is different. Specifically, the cap layer 925 is formed by depositing GaN film having a thickness of about 10 nm while supplying TMG and NH₃ in the MOVPE chamber as a source gas, under the condition that the growth temperature is 740° C. and the growth pressure is 5 kPa.

In the I-V characteristics illustrated in FIGS. 5 and 6, solid lines represent the result of DC measurement, and white circles (o) represent the result of pulsed measurement. The pulsed measurement is performed by measuring a drain current when a drain voltage (Vds) pulse and a gate voltage (Vgs) pulse are applied, after having applied a drain voltage (Vds) of 50V and a gate voltage (Vgs) of −5V as stress. The measurement is performed repeatedly while varying the levels of the drain voltage pulse and the gate voltage pulse.

In the semiconductor device according to the present embodiment, the I-V characteristics obtained by the DC measurement and the I-V characteristics obtained by the pulsed measurement are almost the same, which means that occurrence of the current collapse phenomenon is suppressed. On the other hand, in the semiconductor device having a structure illustrated in FIG. 1, the drain current in the pulsed measurement is less than the drain current in the DC measurement. As the reason for this result, it is assumed that the current collapse phenomenon occurs in the semiconductor device having a structure illustrated in FIG. 1 because the concentration of carbon contained in the cap layer 925 is high, and C contained in the cap layer 925 becomes a defect that traps an electron.

As a result of analyzing the cap layer 25 in the semiconductor device according to the present embodiment using SIMS, the concentration of carbon in the cap layer 25 was 6×10¹⁶ atoms/cm³. On the other hand, the concentration of carbon in the cap layer 925 in the semiconductor device having a structure illustrated in FIG. 1 was 7×10¹⁷ atoms/cm³, which was higher than the concentration of carbon in the cap layer 25 according to the present embodiment. This is because the growth temperature in forming the cap layer 925 in the semiconductor device having a structure illustrated in FIG. 1 by MOVPE is lower than the growth temperature in forming the cap layer 25 in the semiconductor device according to the present embodiment.

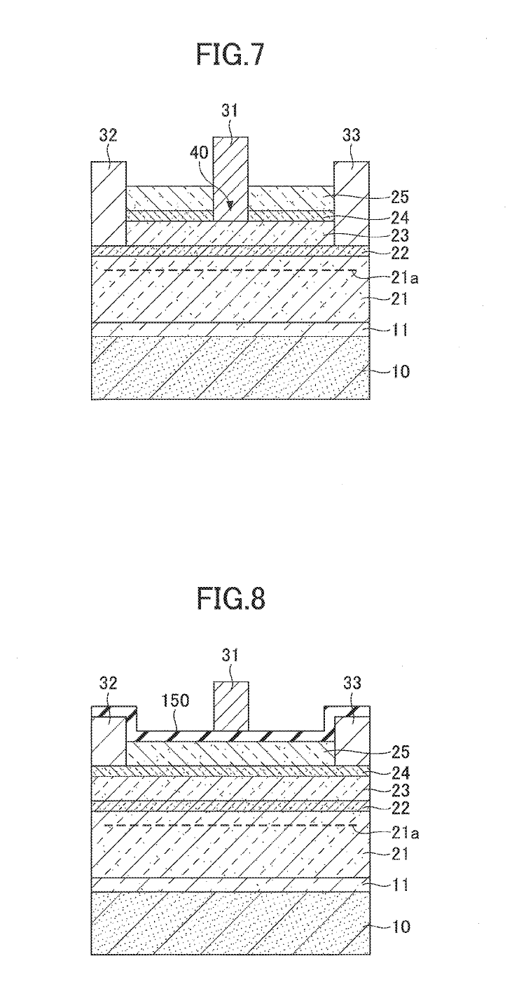

In the semiconductor device according to the present embodiment, as illustrated in FIG. 7, a gate recess 40 may be formed by removing a part of the nitride semiconductor layers located directly underneath the gate electrode 31, and the gate electrode 31 may be formed at the gate recess 40.

The semiconductor device having the structure illustrated in FIG. 7 can be manufactured by removing the cap layer 25 and the desorption prevention layer 24 at a location where the gate electrode 31 is to be formed to form the gate recess 40, and by forming the gate electrode 31 at the gate recess 40. Specifically, after forming the cap layer 25 of the nitride semiconductor layers is finished, the cap layer 25 is coated with a photoresist, and the exposure and development processing are performed using the exposing apparatus, to form a photoresist pattern (not illustrated in the drawings) having an opening at the location where the gate recess 40 is to be formed. Subsequently, the cap layer 25 and the desorption prevention layer 24 existing at a location where the photoresist pattern does not exist are removed by performing dry etching such as RIE to form the gate recess 40. Subsequently, by removing the photoresist pattern (not illustrated in the drawings) using an organic solvent, and by forming the gate electrode 31 at a location where the gate recess 40 is formed using the same method as described above, the semiconductor device having the structure illustrated in FIG. 7 can be manufactured.

### Second Embodiment

### <Semiconductor Device>

Next, a semiconductor device according to the second embodiment will be described. In the semiconductor device according to the present embodiment, as illustrated in FIG. 8, a nucleation layer (not illustrated), a buffer layer 11, an electron transit layer 21, a spacer layer 22, an electron supply layer 23, a desorption prevention layer 24, and a cap layer 25 are layered sequentially on a substrate 10. An insulating film 150 is formed on the cap layer 25, a gate electrode 31 is formed on the insulating film 150, and a source electrode 32 and a drain electrode 33 are formed on the desorption prevention layer 24.

A silicon substrate is used as the substrate 10, and the nucleation layer is formed of AlN. The buffer layer 11 is formed of AlGaN, and may be doped with 3×10¹⁷ atoms/cm³ of Fe as an impurity element to have high resistance. The electron transit layer 21 is formed of GaN, the spacer layer 22 is formed of AlN, the electron supply layer 23 is formed of InAlN, the desorption prevention layer 24 is formed of AlN, and the cap layer 25 is formed of GaN. Because of this structure, 2 DEG 21a is generated in the electron transit layer 21 near the interface of the electron transit layer 21 and the spacer layer 22.

In the semiconductor device according to the present embodiment, the nucleation layer (not illustrated), the buffer layer 11, the electron transit layer 21, the spacer layer 22, the electron supply layer 23, the desorption prevention layer 24, and the cap layer 25, which are nitride semiconductor layers, are formed through epitaxial growth using MOVPE. Further, the insulating film 150 functions as a gate insulating film, and is formed of an oxide film, a nitride film, or an oxynitride film of Si, Al, Hf, Ti, Ta, or W. The insulating film 150 is formed by a film deposition method such as ALD (atomic layer deposition), plasma-enhanced CVD (chemical vapor deposition), sputtering, and the like, so that the thickness is not less than 2 nm and not more than 200 nm. In the semiconductor device according to the present embodiment, the insulating film 150 is formed of an Al₂O₃ (aluminum oxide) film having a thickness of 10 nm.

### <Manufacturing Method of the Semiconductor Device>

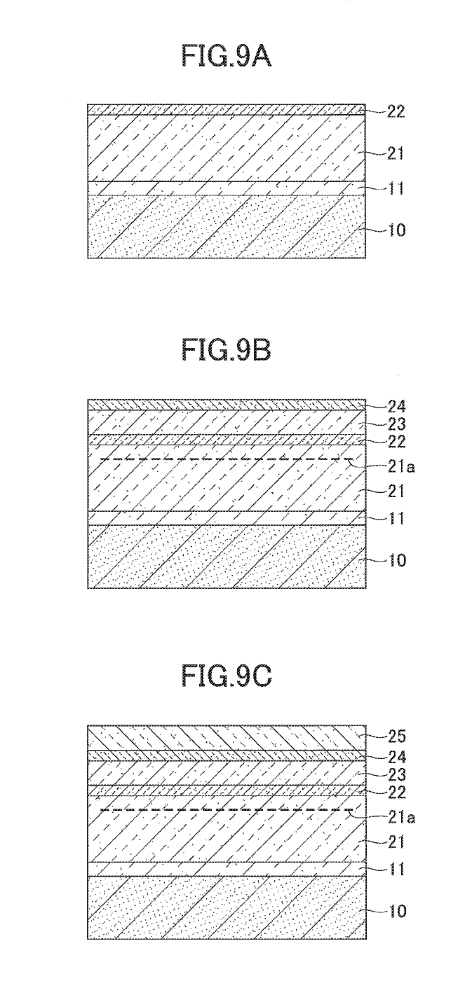

Next, with reference to FIGS. 9 through 11, a method of manufacturing the semiconductor device according to the present embodiment will be described.

First, as illustrated in FIG. 9A, the process of forming the nucleation layer (not illustrated), the buffer layer 11, the electron transit layer 21, and the spacer layer 22 sequentially on a substrate 10 through epitaxial growth using MOVPE is performed.

Specifically, a silicon substrate is used as the substrate 10. The nucleation layer not illustrated is formed by depositing AlN film while supplying trimethylaluminium (TMA) and NH₃ in the MOVPE chamber as a source gas, under the condition that the growth temperature is 1000° C. and the growth pressure is 20 kPa.

The buffer layer 11 is formed by depositing AlGaN film while supplying trimethylgallium (TMG), TMA and NH₃ in the MOVPE chamber as a source gas, under the condition that the growth temperature is 1000° C. and the growth pressure is 20 kPa. The buffer layer 11 is formed by layering three layers of AlGaN films each of which has a different composition ratio. Specifically, the buffer layer 11 is formed so that Al_{0.8}Ga_{0.2}N film, Al_{0.5}Ga_{0.5}N film, and Al_{0.2}Ga_{0.8}N film are layered sequentially on the nucleation layer. The AlGaN films having different composition ratios can be formed by performing deposition while varying the supply ratios of TMA and TMG that are supplied to the chamber. Further, the buffer layer 11 may be doped with approximately 3×10¹⁷ atoms/cm³ of Fe. To dope the buffer layer 11 with Fe, cyclopentadienyl iron (Cp₂Fe) may be supplied during deposition.

The electron transit layer 21 is formed by depositing GaN film having a thickness of about 1 μm while supplying TMG and NH₃ in the MOVPE chamber as a source gas, under the condition that the growth temperature is 1000° C. and the growth pressure is 20 kPa.

The spacer layer 22 is formed by depositing AlN film having a thickness of about 1 nm while supplying TMA and NH₃ in the MOVPE chamber as a source gas, under the condition that the growth temperature is 1040° C. and the growth pressure is 5 kPa.

Next, after lowering the temperature of the substrate to about 740° C., as illustrated in FIG. 9B, the process of forming the electron supply layer 23 and the desorption prevention layer 24 sequentially on the spacer layer 22 is performed.

The electron supply layer 23 is formed by depositing In_{0.17}Al_{0.83}N film having a thickness of about 10 nm while supplying trimethylindium (TMI), TMA and NH₃ in the MOVPE chamber as a source gas, under the condition that the growth temperature is 740° C. and the growth pressure is 5 kPa.

The desorption prevention layer 24 is formed by stopping the supply of TMI just before completing the deposition of the electron supply layer 23 in the process of depositing the electron supply layer 23, and depositing AlN film having a thickness of about 1 nm. Accordingly, the electron supply layer 23 and the desorption prevention layer 24 are formed by continuous growth. By forming the nitride semiconductor layers as described here, 2 DEG 21a is generated in the electron transit layer 21 near the interface of the electron transit layer 21 and the spacer layer 22.

Next, after raising the temperature of the substrate to about 1000° C. again, the process of forming the cap layer 25 on the desorption prevention layer 24 is performed, as illustrated in FIG. 9C.

The cap layer 25 is formed by depositing GaN film having a thickness of about 10 nm while supplying TMG and NH₃ in the MOVPE chamber as a source gas, under the condition that the growth temperature is 1000° C. and the growth pressure is 20 kPa.

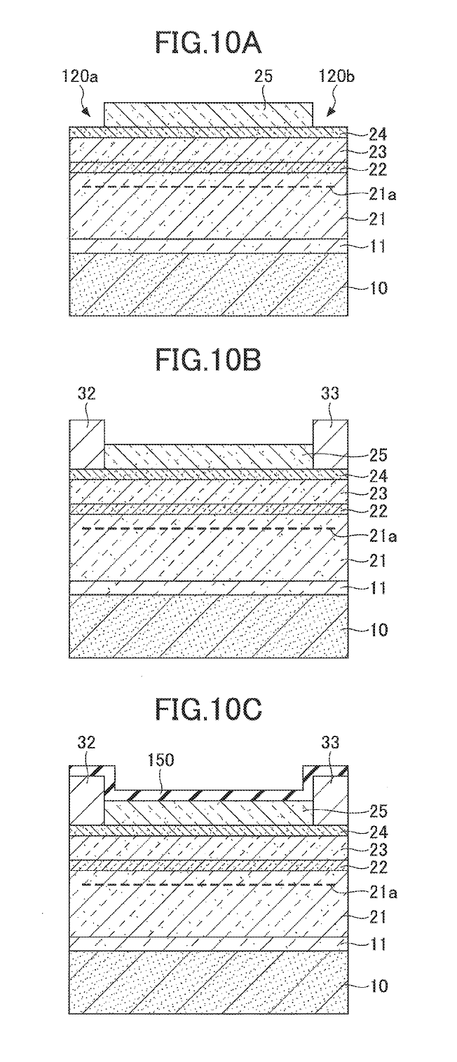

Next, after forming an element isolation region which is not illustrated in the drawings, a process of forming openings 120a and 120b is performed as illustrated in FIG. 10A, by removing the nitride semiconductor layers at locations where the source electrode 32 and the drain electrode 33 are to be formed.

Specifically, the element isolation region which is not illustrated in the drawings is formed by performing the following processes. First, a photoresist pattern (not illustrated in the drawings) is formed having an opening at locations where the element isolation region is to be formed, by applying the photoresist on the cap layer 25 and performing the exposure and development processing using the exposing apparatus. Subsequently, by performing dry etching to remove a part of the nitride semiconductor layers at the opening of the photoresist pattern, or by performing ion implantation to the part of the nitride semiconductor layers, the element isolation region which is not illustrated in the drawings is formed. After the process, the photoresist pattern (not illustrated in the drawings) is removed using an organic solvent.

Next, a photoresist is applied on the cap layer 25 again, and the exposure and development processing are performed using the exposing apparatus, to form a photoresist pattern (not illustrated in the drawings) having openings at locations where the source electrode 32 and the drain electrode 33 are to be formed. Subsequently, the cap layer 25 existing at the area of the nitride semiconductor layers where the photoresist pattern does not exist are removed by performing dry etching such as RIE. By performing this process, on the nitride semiconductor layers, the openings 120a and 120b are formed at the locations where the source electrode 32 and a drain electrode 33 are to be formed. Subsequently, the photoresist pattern (not illustrated in the drawings) is removed using an organic solvent. In the RIE performed here, a gas containing a chlorine component is used as an etching gas.

Next, as illustrated in FIG. 10B, a process of forming the source electrode 32 and the drain electrode 33 is performed. Specifically, a photoresist is applied on the cap layer 25 and the desorption prevention layer 24 which is exposed at the openings 120a and 120b, and the exposure and development processing using the exposing apparatus are performed, to form a photoresist pattern (not illustrated in the drawings) having an opening at the locations where the source electrode 32 and the drain electrode 33 are to be formed. Subsequently, after a metal multilayered film of Ta (20 nm)/Al (200 nm) is formed through a vacuum vapor deposition, by immersing in an organic solvent, the metal multilayered film which is deposited on the photoresist pattern is removed together with the photoresist pattern by lift-off process. As a result of performing this process, by the metal multilayered film remaining on the desorption prevention layer 24, the source electrode 32 is formed at the opening 120a on the nitride semiconductor layers and the drain electrode 33 is formed at the opening 120b on the nitride semiconductor layers. Subsequently, the nitride semiconductor layers are heat-treated in a nitrogen atmosphere at a temperature of about 400° C. to 1000° C., at 550° C. for example, to establish ohmic contact.

Next, as illustrated in FIG. 10C, a process of forming the insulating film 150 on the cap layer 25 is performed so that an Al₂O₃ film having a thickness of 10 nm is formed by ALD and the like.

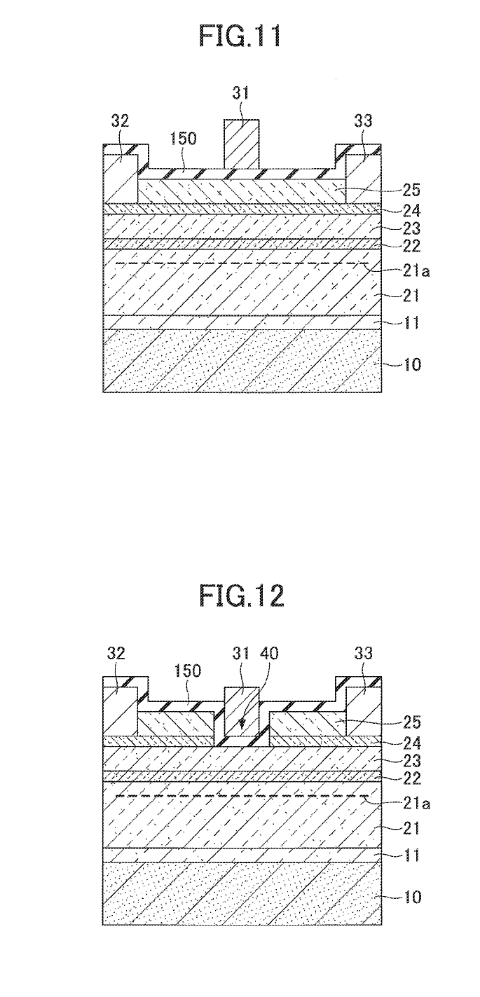

Next, as illustrated in FIG. 11, a process of forming the gate electrode 31 on the insulating film 150 which functions as a gate insulating film is performed. Specifically, a photoresist is applied on the insulating film 150, the source electrode 32, and the drain electrode 33, and the exposure and development processing using the exposing apparatus are performed, to form a photoresist pattern (not illustrated in the drawings) having an opening at a location where the gate electrode 31 is to be formed. Subsequently, after a metal multilayered film of Ni (30 nm)/Au (400 nm) is formed through a vacuum vapor deposition, by immersing in an organic solvent, the metal multilayered film which is deposited on the photoresist pattern is removed together with the photoresist pattern by lift-off process. As a result of this process, the gate electrode 31 is formed by the metal multilayered film remaining on the insulating film 150.

According to these processes, the semiconductor device according to the present embodiment is manufactured.

The contents of the second embodiment other than what was described above are similar to the first embodiment. Also, the contents of the second embodiment can be applied to the semiconductor device having the structure illustrated in FIG. 7 in the first embodiment. That is, as illustrated in FIG. 12, the semiconductor device according to the second embodiment may have a structure such that the insulating film 150 is formed on a gate recess 40 formed by removing a part of the nitride semiconductor layers located directly underneath the gate electrode 31, and that the gate electrode 31 is formed on the insulating film 150 at the gate recess 40. The desorption prevention layer 24 may be placed on a location different from the gate electrode 31 in planar view.

Specifically, the semiconductor device having the structure illustrated in FIG. 12 can be manufactured by performing the following processes. After forming the cap layer 25 of the nitride semiconductor layers is finished, the cap layer 25 is coated with a photoresist, and the exposure and development processing are performed using the exposing apparatus, to form a photoresist pattern (not illustrated in the drawings) having an opening at the location where the gate recess 40 is to be formed. Subsequently, the cap layer 25 and the desorption prevention layer 24 existing at a location where the photoresist pattern does not exist are removed by performing dry etching such as RIE to form the gate recess 40. Subsequently, the photoresist pattern (not illustrated in the drawings) is removed using an organic solvent, the insulating film 150 is formed on the cap layer 25 and on a location of the electron supply layer 23 where the gate recess 40 is formed, and the gate electrode 31 is formed on the insulating film 150 at a location where the gate recess 40 is formed.

### Third Embodiment

Next, a third embodiment will be described. The third embodiment relates to a packaged semiconductor device, a power supply unit, and a high-frequency amplifier.

### <Packaged Semiconductor Device>

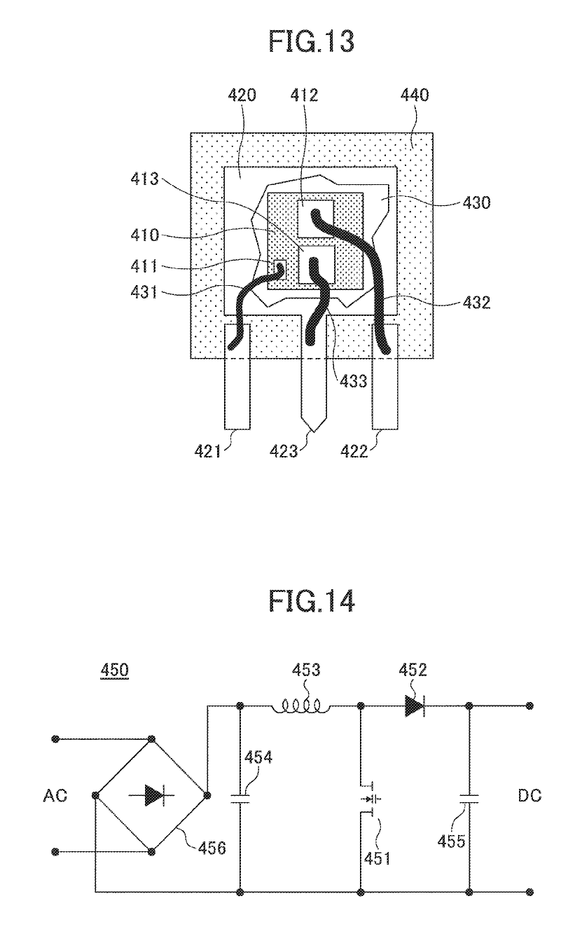

A packaged semiconductor device is a discrete package of the semiconductor device according to the first or second embodiment. Referring to FIG. 13, the discrete packaged semiconductor device will be described. Since FIG. 13 is a schematic diagram illustrating inside of the discrete packaged semiconductor device, some points such as layout of electrodes are different from the points described in the first or second embodiment.

First, by cutting the semiconductor device manufactured by the method according to the first or second embodiment by dicing, a semiconductor chip 410 of an HEMT made of GaN based semiconductor material is formed. The semiconductor chip 410 is fixed on a lead frame 420 using a die attaching agent 430 such as solder. Note that the semiconductor chip 410 corresponds to the semiconductor device according to the first or second embodiment.

Next, a gate electrode 411 is connected to a gate lead 421 with bonding wire 431, a source electrode 412 is connected to a source lead 422 with bonding wire 432, and a drain electrode 413 is connected to a drain lead 423 with bonding wire 433. The bonding wire 431, 432, and 433 is made of metal material such as Al. Also in the present embodiment, the gate electrode 411 is a type of gate electrode pad, and is connected to the gate electrode 31 in the semiconductor device according to the first or second embodiment. Further, the source electrode 412 is a type of source electrode pad, and is connected to the source electrode 32 in the semiconductor device according to the first or second embodiment. Further, the drain electrode 413 is a type of drain electrode pad, and is connected to the drain electrode 33 in the semiconductor device according to the first or second embodiment.

Next, resin sealing with molding resin 440 is performed by transfer molding. By performing the process described here, a discrete package for the semiconductor device with the HEMT semiconductor chip made of GaN based semiconductor material can be manufactured.

### <PFC Circuit, Power Supply Unit, and High-Frequency Amplifier>

Next, a PFC circuit, a power supply unit, and a high-frequency amplifier according to the present embodiment will be described. The PFC circuit, the power supply unit, and the high-frequency amplifier according to the present embodiment adopt the semiconductor device according to the first or second embodiment.

### <PFC Circuit>

The PFC (Power Factor Correction) circuit according to the present embodiment will be described. The PFC circuit according to the present embodiment includes the semiconductor device according to the first or second embodiment.

The PFC circuit according to the present embodiment will be described with reference to FIG. 14. The PFC circuit 450 according to the present embodiment includes a switching element (transistor) 451, a diode 452, a choke coil 453, capacitors 454 and 455, a diode bridge 456, and an alternating current (AC) power source (not illustrated in the drawing). The HEMT which is the semiconductor device according to the first or second embodiment is used as the switching element 451.

In the PFC circuit 450, a drain electrode of the switching element 451, anode terminal of the diode 452, and one terminal of the choke coil 453 are connected with each other. Also, a source electrode of the switching element 451, one terminal of the capacitor 454, and one terminal of the capacitor 455 are connected with each other, and the other terminal of the capacitor 454 and the other terminal of the choke coil 453 are connected with each other. The other terminal of the capacitor 455 and a cathode terminal of the diode 452 are connected with each other, and the alternating current (AC) power source is connected between both terminals of the capacitor 454 via the diode bridge 456. In the PFC circuit 450, direct current (DC) power is output to the terminals of the capacitor 455.

### <Power Supply Unit>

Next, the power supply unit according to the present embodiment will be described. The power supply unit according to the present embodiment includes the HEMT which is the semiconductor device according to the first or second embodiment.

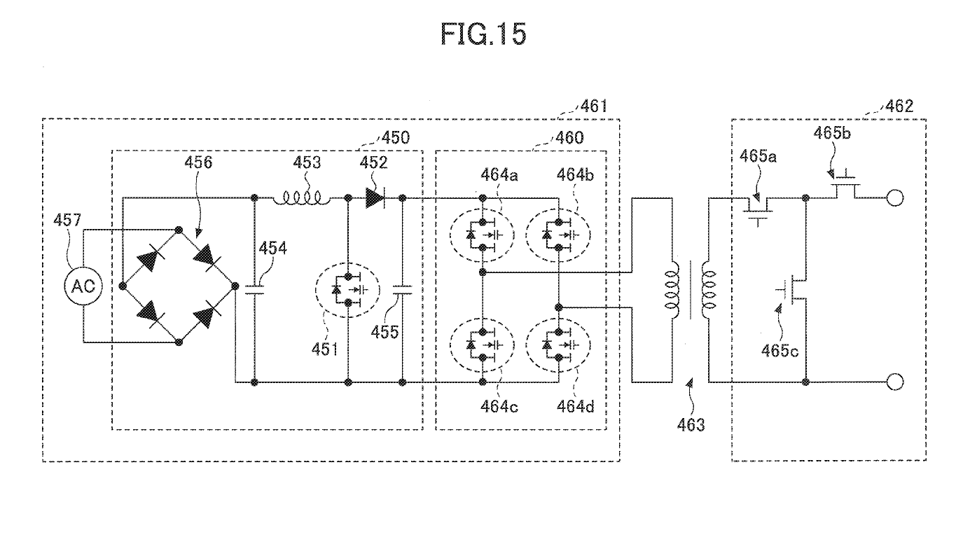

The power supply unit according to the present embodiment will be described with reference to FIG. 15. The power supply unit according to the present embodiment includes the PFC circuit 450 according to the present embodiment described earlier.

The power supply unit according to the present embodiment includes a primary circuit 461 of a high voltage, a secondary circuit 462 of a low voltage, and a transformer 463 disposed between the primary circuit 461 and the secondary circuit 462.

The primary circuit 461 includes the PFC circuit 450 according to the present embodiment described earlier, and an inverter circuit, for example, a full-bridge inverter circuit 460 connected between both terminals of the capacitor 455. The full-bridge inverter circuit 460 includes multiple (4 in the present embodiment) switching elements 464a, 464b, 464c, and 464d. The secondary circuit 462 includes multiple (3 in the present embodiment) switching elements 465a, 465b, and 465c. An alternating current (AC) power source 457 is connected to the diode bridge 456.

In the present embodiment, the HEMT which is the semiconductor device according to the first or second embodiment is used for the switching element 451 contained in the PFC circuit 450 of the primary circuit 461. Further, the HEMT which is the semiconductor device according to the first or second embodiment is used for the switching elements 464a, 464b, 464c, and 464d in the full-bridge inverter circuit 460. On the other hand, a silicon-based general MIS-FET is used for the switching elements 465a, 465b, and 464c in the secondary circuit 462.

### <High-Frequency Amplifier>

Next, the high-frequency amplifier according to the present embodiment will be described. The high-frequency amplifier according to the present embodiment includes the HEMT which is the semiconductor device according to the first or second embodiment.

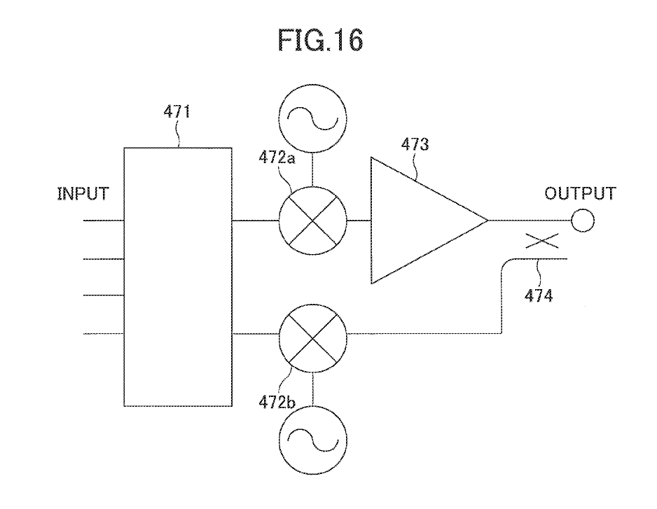

The high-frequency amplifier according to the present embodiment will be described with reference to FIG. 16. The high-frequency amplifier according to the present embodiment includes a digital predistortion circuit 471, mixers 472a and 472b, a power amplifier 473, and a directional coupler 474.

The digital predistortion circuit 471 compensates non-linear distortion in an input signal. The mixer 472a mixes an input signal of which the non-linear distortion was compensated with an AC signal. The power amplifier 473 amplifies the input signal mixed with the AC signal, and the power amplifier 473 includes the HEMT which is the semiconductor device according to the first or second embodiment. The directional coupler 474 is used for monitoring the input signal or an output signal. The high-frequency amplifier illustrated in FIG. 16 can also, in accordance with the switching operation by users for example, mix an output-side signal with an AC signal using the mixer 472b, and can send the mixed signal to the digital predistortion circuit 471.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a first semiconductor layer formed of a nitride semiconductor above a substrate;
a second semiconductor layer formed of a material including InAlN or InAlGaN above the first semiconductor layer;
a third semiconductor layer formed of a material including AlN above the second semiconductor layer;
a fourth semiconductor layer formed of a material including GaN above the third semiconductor layer;
a gate electrode formed above the fourth semiconductor layer; and
a source electrode and a drain electrode formed on any one of the second semiconductor layer, the third semiconductor layer, and the fourth semiconductor layer.

2. The semiconductor device as claimed in claim 1, wherein an insulating film is formed between the fourth semiconductor layer and the gate electrode.

3. A semiconductor device comprising:
a first semiconductor layer formed of nitride semiconductor above a substrate;
a second semiconductor layer formed of a material including InAlN or InAlGaN above the first semiconductor layer;
a third semiconductor layer formed of a material including AlN above the second semiconductor layer;
a fourth semiconductor layer formed of a material including GaN above the third semiconductor layer;
a gate recess formed by removing a part of the fourth semiconductor layer, or by removing a part of the third semiconductor layer and a part of the fourth semiconductor layer;
a gate electrode formed at the gate recess; and
a source electrode and a drain electrode formed on any one of the second semiconductor layer, the third semiconductor layer, and the fourth semiconductor layer.

4. The semiconductor device as claimed in claim 3, wherein an insulating film is formed between the third semiconductor layer and the gate electrode, or between the second semiconductor layer and the gate electrode.

5. The semiconductor device as claimed in claim 1, wherein the third semiconductor layer is disposed between the source electrode and the drain electrode.

6. The semiconductor device as claimed in claim 5, wherein the third semiconductor layer is disposed on a location different from the gate electrode in planar view.

7. The semiconductor device as claimed in claim 2, wherein the insulating film comprises any one of an oxide film, a nitride film, and an oxynitride film, of Si, Al, Hf, Ti, Ta, or W.

8. The semiconductor device as claimed in claim 1, further comprising a fifth semiconductor layer between the first semiconductor layer and the second semiconductor layer, wherein the fifth semiconductor layer is formed of a material including AlN.

9. The semiconductor device as claimed in claim 1, wherein the first semiconductor layer is formed of a material including GaN.

10. The semiconductor device as claimed in claim 1, wherein a thickness of the third semiconductor layer is not less than 0.2 nm and not more than 2 nm.

11. The semiconductor device as claimed in claim 1, wherein a concentration of carbon in the fourth semiconductor layer is not more than 1×10¹⁷ atoms/cm³.

12. The semiconductor device as claimed in claim 1, wherein the substrate is formed of a material including any one of silicon, GaN, sapphire, and SiC.

13. A semiconductor device manufacturing method comprising:
forming a first semiconductor layer by a nitride semiconductor above a substrate;
forming a second semiconductor layer by a material including InAlN or InAlGaN above the first semiconductor layer;
forming a third semiconductor layer by a material including AlN above the second semiconductor layer;
forming a fourth semiconductor layer by a material including GaN above the third semiconductor layer;
forming a source electrode and a drain electrode on any one of the second semiconductor layer, the third semiconductor layer, and the fourth semiconductor layer; and
forming a gate electrode above the fourth semiconductor layer.

14. The semiconductor device manufacturing method as claimed in claim 13, further comprising:
forming an insulating film on the fourth semiconductor layer before the forming of the gate electrode and after the forming of the fourth semiconductor layer,
wherein the forming of the gate electrode results in the gate electrode being formed on the insulating film.

15. The semiconductor device manufacturing method as claimed in claim 13,
wherein the first semiconductor layer, the second semiconductor layer, the third semiconductor layer, and the fourth semiconductor layer are formed through an epitaxial growth, and
a temperature during the forming of the fourth semiconductor layer is higher than a temperature during the forming of the second semiconductor layer and the third semiconductor layer.

16. A power supply unit comprising the semiconductor device according to claim 1.

17. An amplifier comprising the semiconductor device according to claim 1.
